(19) United States
(12) Patent Application Publication
(10) Pub. No.: US 2024/0407199 A1
(43) Pub. Date: Dec. 5, 2024

(54) OLED SUB-PIXEL CIRCUIT FORMATION AND STRUCTURE

(71) Applicant: Applied Materials, Inc., Santa Clara, CA (US)

(72) Inventors: Jong Yun KIM, Hwaseong-si (KR); Ji Young CHOUNG, Hwaseong-si (KR); Kim Seong SIM, Singapore (SG); Yu-Hsin LIN, Zhubei City (TW)

(21) Appl. No.: 18/661,371

(22) Filed: May 10, 2024

Related U.S. Application Data
(60) Provisional application No. 63/505,084, filed on May 31, 2023.

(51) Int. Cl. H10K 59/122; H10K 59/12; H10K 71/16

(52) U.S. Cl. CPC H10K 59/122; H10K 59/1201; H10K 71/164

(57) ABSTRACT

Embodiments of the present disclosure provide methods for forming sub circuits (e.g., sub-pixel circuits). One example sub circuit generally includes a backplane layer disposed over a substrate, a pixel defining layer (PDL) disposed over the backplane layer, the PDL exposing anodes disposed over the backplane layer and the substrate, and a plurality of walls disposed over the PDL, wherein the plurality of walls define a plurality of gaps, wherein the plurality of walls and the plurality of gaps define one or more unit pixels, and wherein the one or more unit pixels each comprise a sub-pixel. Each sub-pixel may include an anode defined by the PDL, an organic light-emitting diode (OLED) material disposed over the anode, and a cathode disposed over the OLED material and the plurality of walls.

### CROSS-REFERENCE TO RELATED APPLICATION(S)

This application claims the benefit of and priority to U.S. Provisional Application 63/505,084 filed on May 31, 2023, which is assigned to the assignee hereof and hereby expressly incorporated by reference herein in its entirety as if fully set forth below and for all applicable purposes.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. OLED devices include a plurality of sub-pixels (e.g., a sub-pixel circuit) defined by adjacent pixel-defining layer (PDL) structures. Each sub-pixel has an anode, OLED material disposed on the anode, and a cathode disposed on the OLED material. Many augmented, virtual, and mixed reality applications require the use of OLED devices with a high pixel density. However, current fine metal mask (FMM) and lithography technology may not be suitable for forming OLED devices with a high pixel density.

Accordingly, what is needed in the art are improved sub-pixel circuits with increased pixel density and improved OLED performance and methods of forming the same.

### SUMMARY

Embodiments of the present disclosure provide a sub circuit. The sub circuit generally includes a backplane layer disposed over a substrate, a pixel defining layer (PDL) disposed over the backplane layer, the PDL exposing anodes disposed over the backplane layer and the substrate, and a plurality of walls disposed over the PDL, where the plurality of walls define a plurality of gaps, where the plurality of walls and the plurality of gaps define one or more unit pixels, and where the one or more unit pixels each include a sub-pixel. Each sub-pixel may include an anode defined by the PDL, an organic light-emitting diode (OLED) material disposed over the anode, and a cathode disposed over the OLED material and the plurality of walls.

Embodiments of the present disclosure provide a method. The method generally includes positioning a substrate, the substrate including one or more unit pixels, where each of the one or more unit pixels comprises a sub-pixel opening, where each sub-pixel opening comprises an anode defined by a plurality of PDL structures, where each of the one or more unit pixels is partially surrounded by a plurality of walls, where the plurality of walls define a plurality of gaps, and where the plurality of walls and the plurality of gaps define the one or more unit pixels. The method also generally further includes depositing a first portion of OLED material on a first portion of the one or more unit pixels at a first orientation, the first orientation formed by a first position of the substrate and a first orientation of an evaporation deposition source, depositing a second portion of OLED material on a second portion of the one or more unit pixels at a second orientation, the second orientation formed by a second position of the substrate and a second orientation of the evaporation deposition source, depositing a third portion of OLED material on a third portion of the one or more unit pixels at a third orientation, the third orientation formed by a third position of the substrate and a third orientation of the evaporation deposition source, and disposing a cathode over the first portion of OLED material, the second portion of OLED material, and the third portion of OLED material.

Embodiments of the present disclosure provide a sub circuit. The sub circuit generally includes a substrate, a PDL disposed over the substrate, the PDL exposing anodes disposed over the substrate, and a Y-shaped wall disposed over the PDL. The Y-shaped wall partially surrounds a unit pixel, where the unit pixel includes three sub-pixels.

Embodiments of the present disclosure provide a method. The method generally includes positioning a substrate, the substrate including a unit pixel, where the unit pixel comprises three sub-pixel openings, where each sub-pixel opening comprises an anode defined by a plurality of PDL structures, and where the unit pixel is partially surrounded by a Y-shaped wall. The method also generally includes depositing OLED material over three portions of the unit pixel, where the OLED material is deposited at three orientations, each orientation corresponding to deposition in a sub-pixel opening of the three sub-pixel openings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit, according to one or more of the embodiments described herein.

FIG. 1B is a schematic, top-view of a sub-pixel circuit, according to one or more of the embodiments described herein.

FIG. 2 is a flow diagram illustrating an example method for forming a sub-pixel circuit, according to one or more of the embodiments described herein.

FIGS. 3A-3J are schematic, cross-sectional view of a sub-pixel circuit during formation, according to one or more of the embodiments described herein.

FIGS. 4A, 4B, and 4C are schematic, top-views of a sub-pixel circuit during a deposition process, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a display that includes organic light emitting diodes (OLEDs) and methods of forming the same. More specifically, embodiments provided herein generally relate to sub-pixel circuits and methods of forming sub-pixel circuits that may be utilized in OLED displays. The OLED displays disclosed herein may be used in any device that includes a display, including augmented, virtual, and mixed reality devices, as well as other devices with displays, including mobile phones and televisions.

In some embodiments, a sub-pixel circuit may contain a number of unit pixels, each unit pixel including a number of sub-pixels arrayed in a triangular array. Each sub-pixel may have the OLED material configured to emit a white, red, green, blue or other color light when energized. For example, the OLED material of a first sub-pixel emits a red light when energized, the OLED material of a second sub-pixel emits a green light when energized, and the OLED material of a third sub-pixel emits a blue light when energized. That is, each of three sub-pixels may be configured to emit a different color when energized. Each unit cell may be partially surrounded by a number of walls, the walls partially separating adjacent unit pixels and forming a number of gaps between adjacent unit pixels. In some embodiments, one or more walls may be a Y-shaped self-mask. One or more of the walls may not literally be Y-shaped. One or more of the walls may be other various shapes and/or may include various curves. The shape and/or curves of the walls may be manipulated to enable the formation of desired sub-pixel circuits. In some embodiments, the one or more walls may include walls having different shapes and/or curves. The gaps between adjacent walls allow a current path of the sub-pixel circuit to be continuous through a cathode of the sub-pixel circuit. In addition, the sub-pixel circuit may be formed using oblique deposition for emission material layer (EML) deposition for red, green, and blue colors. The deposition process may include an evaporation process. As a result, the thickness of the deposited OLED material may not increase material consumption. Further, the angle of deposition (which includes an emission angle and an evaporation angle) used during the deposition of the OLED material may be carefully controlled during formation of the sub-pixels in the sub-pixel circuit. Controlling the angle of deposition results in a more stable open area (e.g., the area where the OLED material is deposited) and shadow area (e.g., the area where the OLED material is not deposited as a result of the walls) formation.

Embodiments of the present disclosure may result in a sub-pixel circuit formed without the use of conventional fine metal mask (FMM) and lithography technology. In addition, a display utilizing the sub-pixel circuit formation and structure disclosed herein also benefits from increased pixel density (PPI).

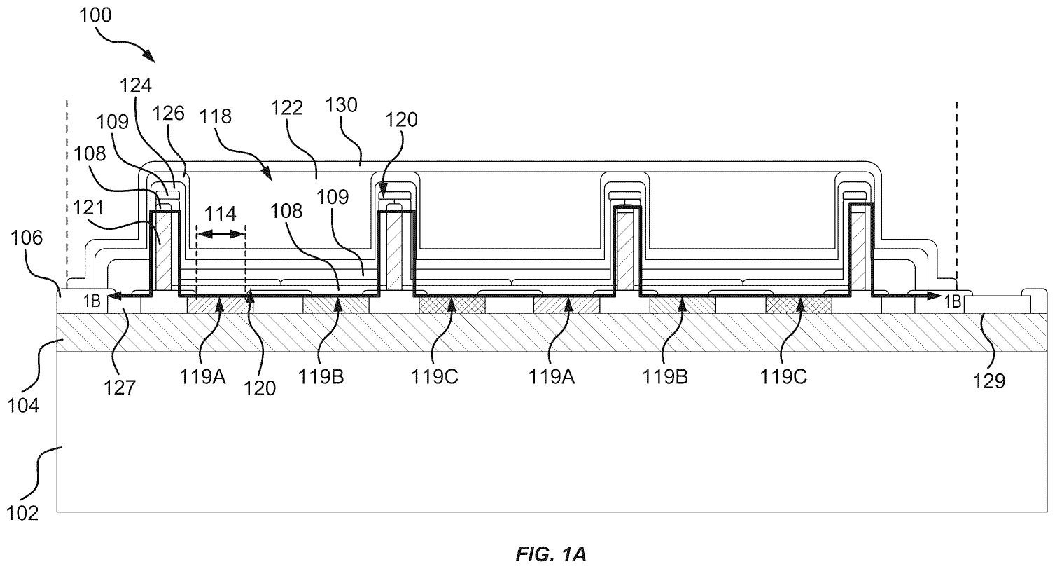

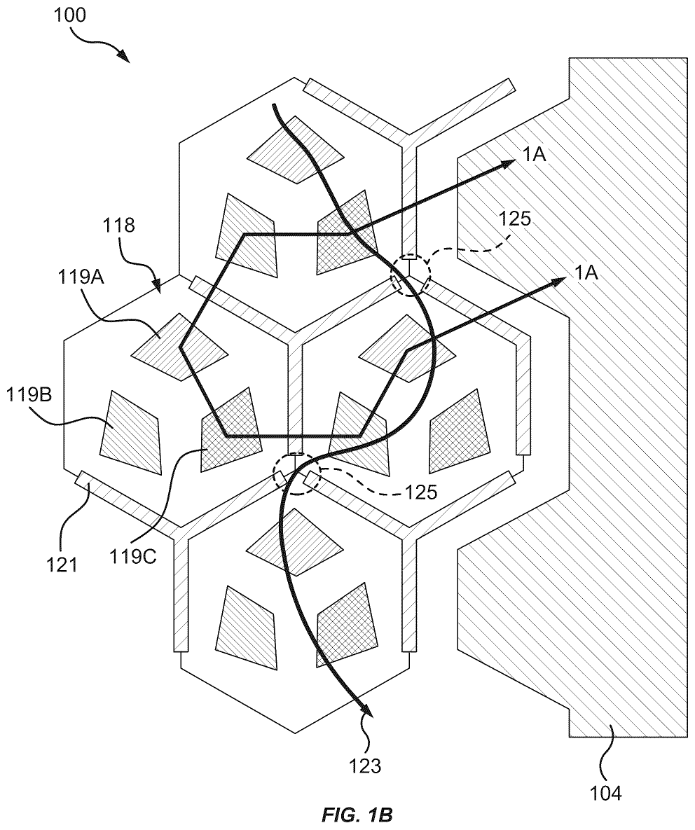

FIG. 1A is a schematic, cross-sectional view of a sub-pixel circuit 100, according to one or more of the embodiments described herein. The sub-pixel circuit 100 may represented an active area of a panel. The sub-pixel circuit 100 includes a substrate 102, and a metal layer 104 disposed over the substrate 102. The metal layer 104 may be implemented and/or referred to as a backplane layer. The backplane layer may control the amount of current needed for sub-pixel emission. FIG. 1B is a schematic, top-view of the sub-pixel circuit 100, according to one or more of the embodiments described herein. The arrows marked 1B of FIG. 1A align to the arrows marked 1A of FIG. 1B. Therefore, FIGS. 1A and 1B are described together for clarity.

The substrate 102 may include, but is not limited to, silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), silicon nitride (Si₃N₄), or sapphire containing materials. The metal layer 104 may be implemented as a thin-film transistor (TFT) layer. The metal layer 104 may include, but is not limited to, chromium, titanium, gold, silver, copper, aluminum, indium tin oxide (ITO), a combination thereof, or other suitably conductive materials. The metal layer 104 may be transparent or reflective depending on whether the sub-pixel circuit 100 will be utilized as a bottom emission display or a top emission display.

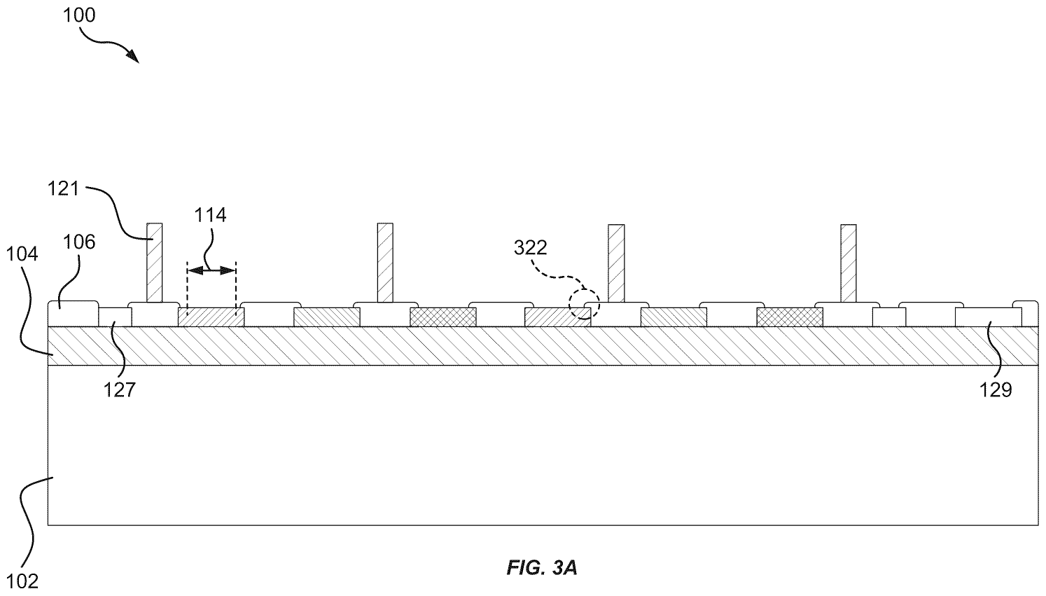

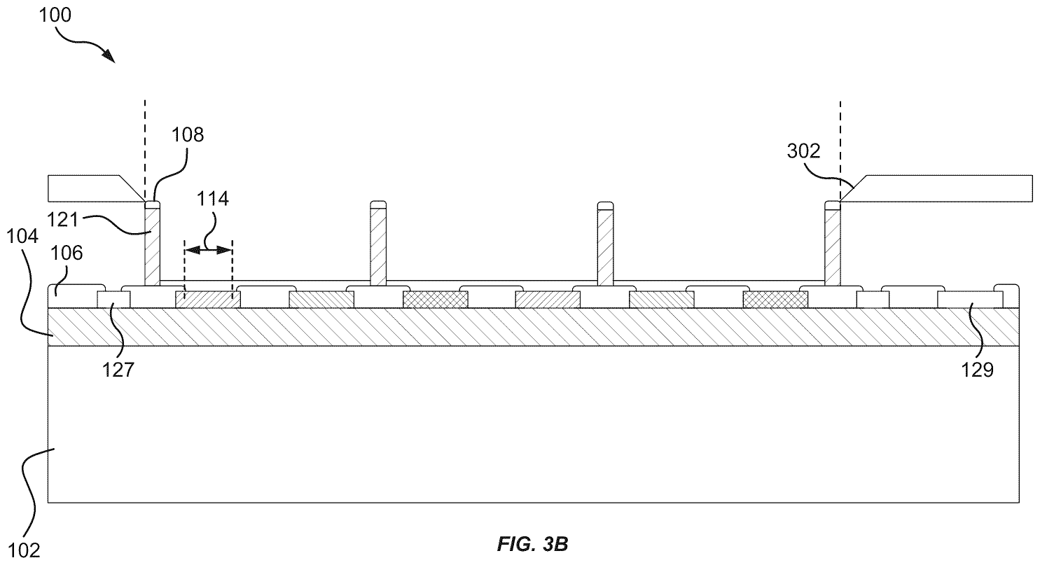

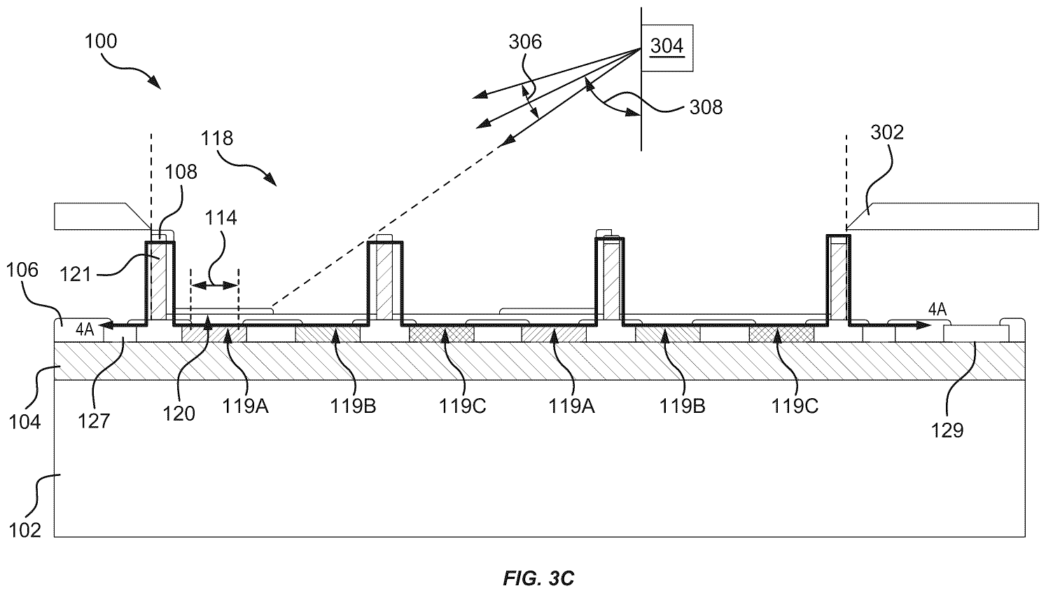

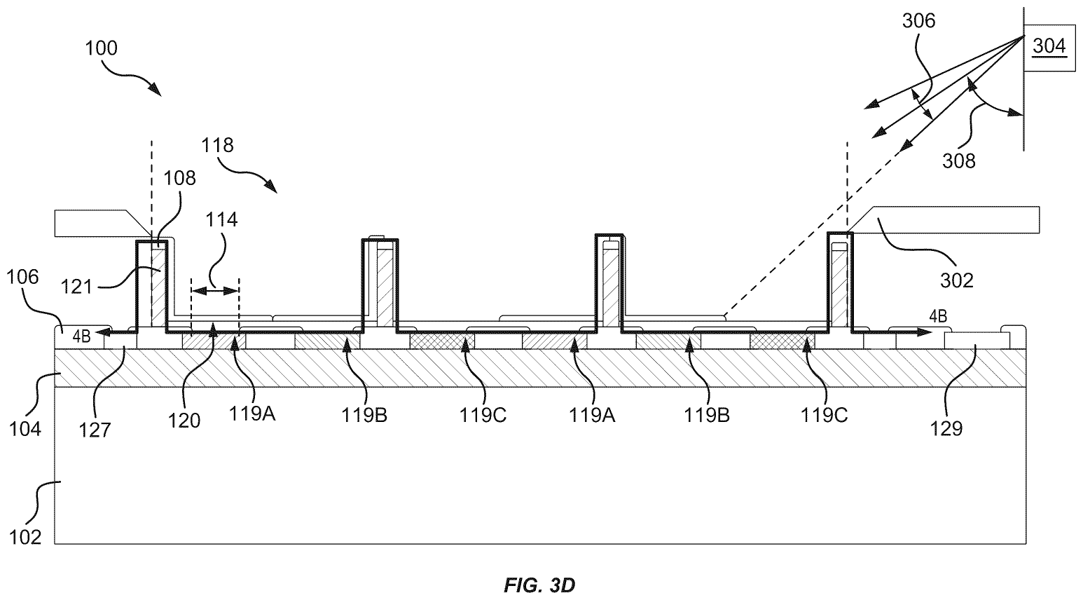

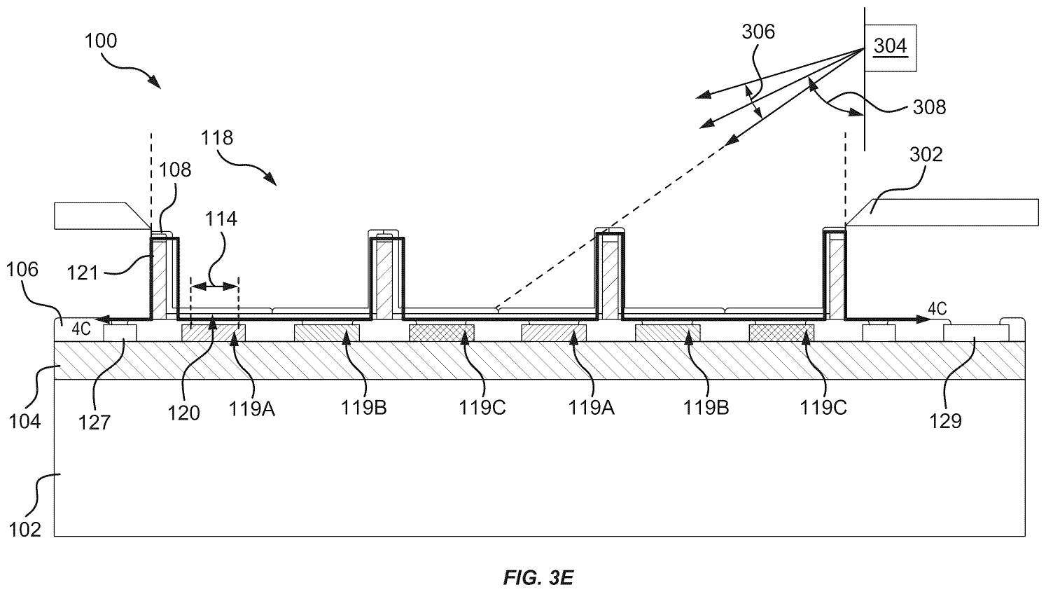

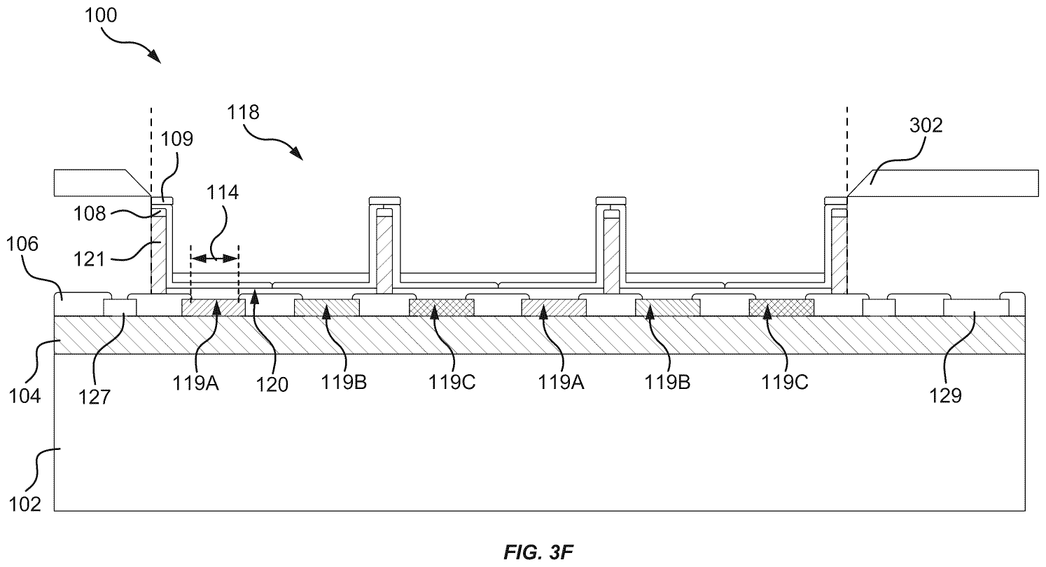

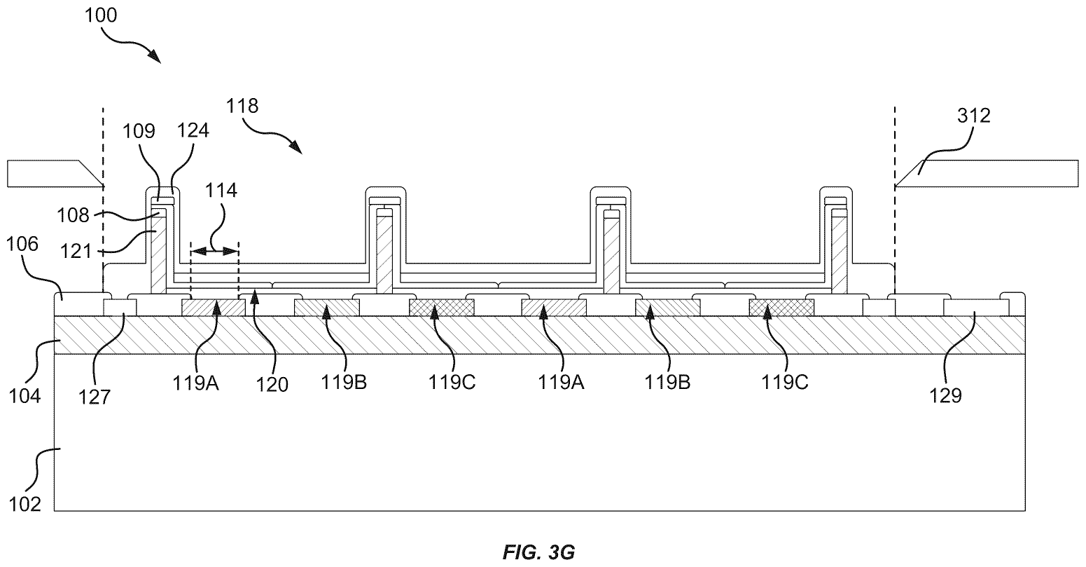

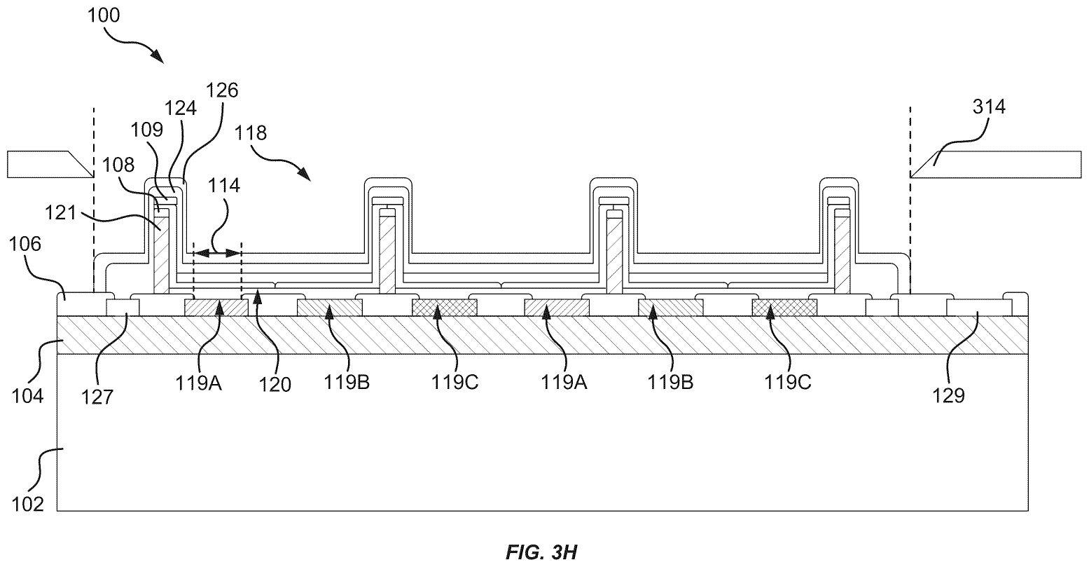

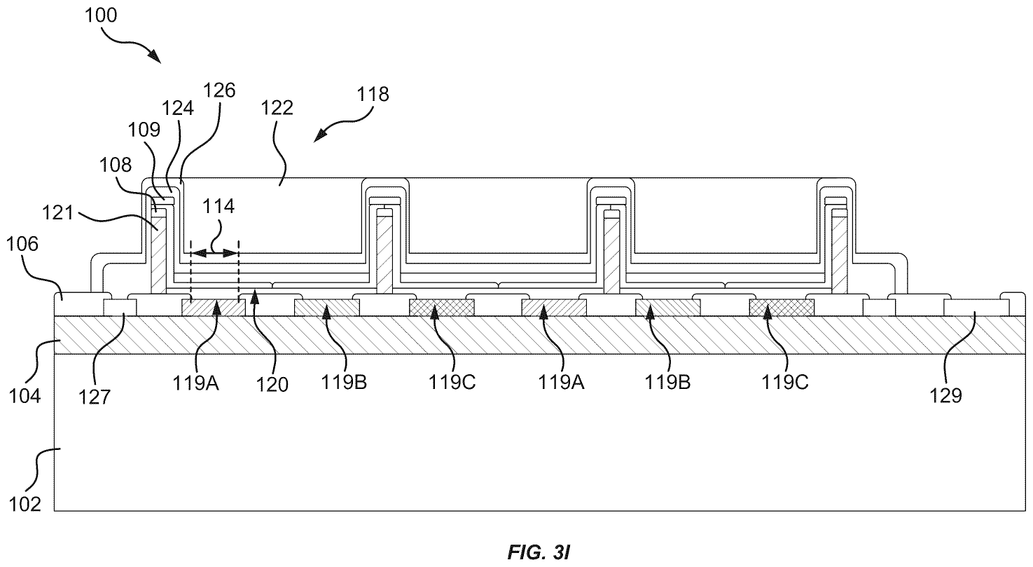

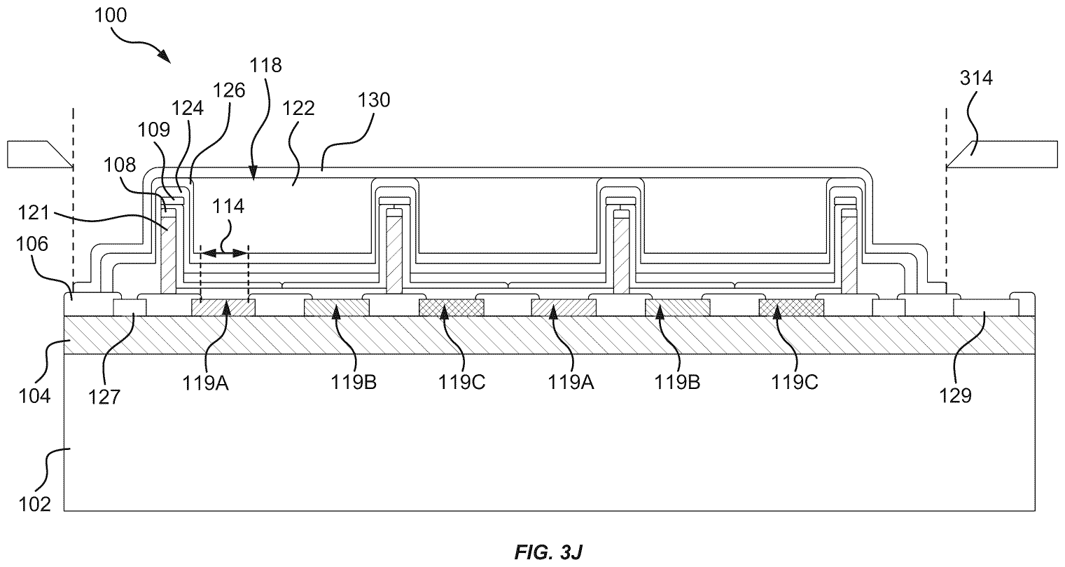

In some embodiments, a pixel-defining layer (PDL) structure 106 may be disposed on the metal layers 104 and the substrate 102. Openings in the PDL structure 106 expose anodes 114 of the metal layer 104. In some embodiments, the PDL structure 106 includes an inorganic insulator material. The inorganic insulator material may include, but is not limited to, SiO₂, Si₃N₄, silicon oxynitride (Si₂N₂O), magnesium fluoride (MgF₂), or combinations thereof. The sub-pixel circuit 100 includes one or more unit pixels 118. Each of the one or more unit pixels 118 includes anodes 114 of the metal layer 104 defined by adjacent PDL structures 106. In some cases, the PDL structure 106 may include one or more tapered surfaces 322 (with corresponding taper angles), as shown in FIG. 3A. Though the tapered surfaces 322 are only shown in FIG. 3A, the tapered surfaces 322 may be included in the PDL structures 106 in any other Figures and embodiments in this application.

The sub-pixel circuit 100 may include a number of walls (e.g., self-mask walls) 121 arranged on the boundaries between adjacent unit pixels 118, as illustrated in FIGS. 1A and 1B. In some embodiments, the walls 121 are disposed over the PDL structures 106. In other embodiments, the walls 121 are disposed over the metal layer 104 and the substrate 102. In the embodiments where the walls 121 are disposed over the metal layer 104 and the substrate 102, the sub-pixel circuit 100 does not include the PDL structures 106.

The walls 121 may be Y-shaped walls, as illustrated. The walls 121 may not literally be Y-shaped. The walls 121 may be other various shapes and/or may include various curves. The shape and/or curves of the walls 121 may be manipulated to enable the formation of desired sub-pixel circuits. In some embodiments, the walls 121 may include walls having different shapes and/or curves. An aspect ratio of the walls 121 may be defined as a ratio of a height of the walls 121 to a width of the walls 121 and may be between 1 to 1 and 10 to 1. For example, the aspect ratio (height to width) may be 6 to 1. The walls 121 may partially surround each unit pixel 118, leavings gap 125 between adjacent walls, also as illustrated in FIG. 1B. Each unit pixel 118 may include a number of sub-pixels 119. For example, each unit pixel 118 may include three sub-pixels 119A, 119B, 119C, as illustrated in FIG. 1B. In some embodiments, the sub-pixels 119A, 119B, 119C of each unit pixel 118 united may be arranged in a triangular array. Each sub-pixel 119A, 119B, 119C may be diamond-shaped to maximize the resultant aperture ratio.

One or more of a hole injection layer (HIL), a hole transport layer (HTL), an electron injection layer (EIL), and an electron transport layer (ETL) may be disposed over at least part of the sub-pixel circuit 100. In the examples illustrated in FIGS. 1A and 3A-3J, the sub-pixel circuit 100 includes one or both of the HIL and the HTL, illustrated as anode-defining layer (ADL) 108. The ADL 108 is also referred to as a common layer. The ADL 108 may include one or more of a hole injection layer (HIL) and a hole transport layer (HTL). In this example, the ADL 108 is disposed over each unit pixel 118 and each wall 121 of the sub-pixel circuit 100, by using a common metal mask 302.

Each unit pixel 118 may include an organic light-emitting diode (OLED) material 120. The OLED material 120 may be disposed over the ADL 108 (which includes one or both of the HIL and the HTL). In some embodiments, the OLED material 120 is also disposed on the adjacent PDL structures 106. The OLED material 120 may be deposited via an oblique deposition process. In some embodiments, the oblique deposition process may involve an evaporation process. The walls 121 and the evaporation angle set by an evaporation source 304 define the deposition angles (e.g., the walls 121 provide for a shadowing effect during evaporation deposition of the OLED material 120 with the evaporation angle set by the evaporation source 304). In order to deposit at a particular angle, the evaporation source 304 is configured to emit the OLED material 120 at a particular angle with regard to the walls 121. By adjusting the angle of deposition by manipulating the orientation of one or both of the evaporation source 304 and the orientation of the sub-pixel circuit 100, the evaporation source 304 can deposit the OLED material 120 at different angles to adjust where the OLED material 120 is disposed on the sub-pixel circuit 100.

The OLED material 120 is configured to emit a white, red, green, blue or other color light when energized. For example, the OLED material 120 of each sub-pixel 119A, 119B, 119C of the unit pixel 118 is configured to emit one of a red light when energized, emit a green light when energized, emit a blue light when energized, or emit a white light when energized. That is, each of three sub-pixels may be configured to emit a different color when energized. In the example illustrated in FIGS. 1A, 1B, and 3A-3J, each unit pixel 118 in the sub-pixel circuit 100 includes a sub-pixel 119A configured to emit a red light when energized, a sub-pixel 119B configured to emit a green light when energized, and a sub-pixel 119C configured to emit a blue light when energized. However, the OLED material 120 of each sub-pixel 119A, 119B, 119C of each unit pixel 118 may be configured to emit any color light when energized, as desired.

One or more of an EIL and an ETL may be disposed over the OLED material 120. In the example illustrated in FIGS. 1A and 3A-3J, the sub-pixel circuit includes one or both of the EIL and the ETL, illustrated as layer 109. In this example, the layer 109 is disposed over each unit pixel 118 and each wall 121 of the sub-pixel circuit 100, by using a common metal mask 302. In some embodiments, the one or more of the EIL and the ETL may be included in the OLED material 120.

A cathode 124 may be disposed over the layer 109 (which includes one or both of the ETL and the EIL). The cathode 124 includes a conductive material, such as a metal. For example, the cathode 124 may include, but is not limited to, chromium, titanium, aluminum, ITO, or a combination thereof. In some embodiments, the cathode 124 may include a mixture of silver (Ag) and magnesium (Mg). In this configuration the cathode 124 contacts bus-bars 127 outside of an active area of the sub-pixel circuit 100.

The sub-pixel circuit 100 may include a first encapsulation layer 126 (e.g., thin film encapsulation (TFE) layer) disposed over the cathode 124. The first encapsulation layer 126 may be or may correspond to a local passivation layer. The first encapsulation layer 126 of a respective unit pixel 118 is disposed over the cathode 124 (and the OLED material 120) and the PDL structures 106. The first encapsulation layer 126 includes a non-conductive inorganic material, such as the silicon-containing material. The silicon-containing material may include Si₃N₄ containing materials.

The sub-pixel circuit 100 may include a plug 122 disposed over the first encapsulation layer 126. The plug 122 may include, a photoresist, a color filter, or a photosensitive monomer. The plug 122 have a plug transmittance that is matched or substantially matched to an OLED transmittance of the OLED material 120. The plug 122 may each be the same material and match the OLED transmittance. The plug 122 may be different materials that match the OLED transmittance of each respective sub-pixel of the plurality of sub-pixels 119A, 119B, 119C. The matched or substantially matched resist transmittance and OLED transmittance allow for the plug 122 to remain over the sub-pixels 119A, 119B, 119C without blocking the emitted light from the OLED material 120. The plug 122 is able to remain in place and thus do not require a lift off procedure to be removed from the sub-pixel circuit 100. In some embodiments, the plug 122 may be an inkjet layer. The inkjet layer may include an acrylic material.

The sub-pixel circuit 100 may include a second encapsulation layer 130 disposed over the plug 122. The second encapsulation layer 130 may be or may correspond to a local passivation layer. The second encapsulation layer 130 of a respective unit pixel 118 is disposed over the cathode 124 (and the OLED material 120) and the PDL structures 106. The second encapsulation layer 130 includes a non-conductive inorganic material, such as the silicon-containing material. The silicon-containing material may include Si₃N₄ containing materials. In some embodiments, the sub-pixel circuit 100 also includes a source/drain (S/D) pad 129. The S/D pad 129 may represent a representative electrode for signal input.

An example of current flow to activate the plurality of sub-pixels 119A, 119B, 119C in the sub-pixel circuit 100 is indicated by a line 123, which is depicted in FIG. 1B. As shown in FIG. 1B, current flows through the gaps 125 of the sub-pixel circuit 100, which permits a continuous current path through the cathode 124. The current flows to the cathode 124 disposed along the sub-pixel circuit 100 to the bus-bars 127. Thus, current is operable to flow through the sub-pixel circuit 100. The current also flows from the cathode 124 to the OLED material 120 and into the metal layer 104 of the sub-pixel circuit 100. The metal layer 104 is provided current, allowing for the activation of the sub-pixels 119A, 119B, 119C in the sub-pixel circuit 100.

The sub-pixels 119A, 119B, 119C in the unit pixels 118 are operable to emit light. The sub-pixel circuit 100 is operable to activate each unit pixel 118 individually and independently. In some embodiments, the sub-pixels 119A, 119B, 119C in each of the unit pixels 118 are mono-colored. In other embodiments, each of the sub-pixels 119A, 119B, 119C in the unit pixels 118 are operable to emit a different colored light.

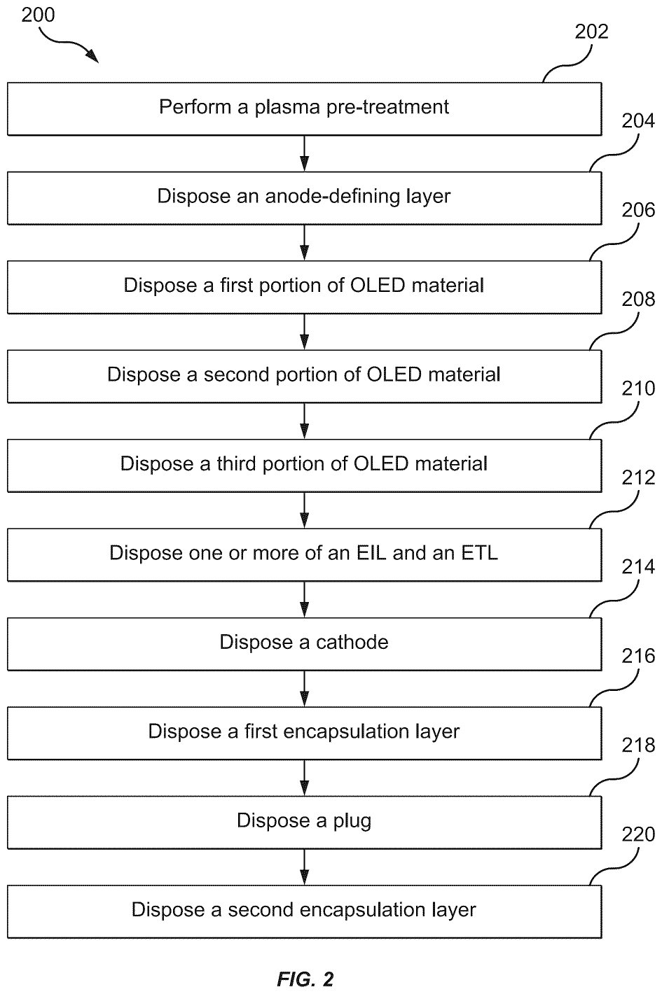

FIG. 2 is a flow diagram illustrating an example method 200 for forming a sub-pixel circuit 100, according to one or more of the embodiments described herein. FIGS. 3A-3J are schematic, cross-sectional view of a sub-pixel circuit 100 during one or more of the forming activities illustrated in FIG. 2, according to one or more of the embodiments described herein. Therefore, FIG. 2 and FIGS. 3A-3J are herein described together for clarity. It is assumed that the metal layer 104 was previously disposed over the substrate 102, and that the PDL structure 106 was also previously disposed over the metal layer 104. The metal layer 104 may be patterned on the substrate 102. In some embodiments, the metal layer 104 is pre-patterned on the substrate 102. For example, the substrate 102 is a pre-patterned ITO glass substrate. In addition, it is also assumed that a plurality of walls (e.g., self-mask walls) 121 arranged on the boundaries between adjacent unit pixels 118 have been previously formed, and that openings in the PDL structure 106 expose anodes 114 of the metal layer 104. The openings in the PDL structure 106 that expose anodes 114 of the metal layer 104 may be referred to as sub-pixel openings before deposition of the OLED material 120 (e.g., operations 206, 208, 210). In some cases, the PDL structure 106 may include one or more tapered surfaces 322 (with corresponding taper angles), as shown in FIG. 3A. Though the tapered surfaces 322 are only shown in FIG. 3A, the tapered surfaces 322 may be included in the PDL structures 106 in any other Figures and embodiments in this application. The walls 121 may include dielectric material and/or may be Y-shaped, as illustrated in FIG. 1B. As described above, the walls 121 may not literally be Y-shaped. The walls 121 may be other various shapes and/or may include various curves. The shape and/or curves of the walls 121 may be manipulated to enable the formation of desired sub-pixel circuits (e.g., with OLED material 120 deposited and a continuous current path, as described herein). In some embodiments, the walls 121 may include walls having different shapes and/or curves. An aspect ratio of the walls 121 may be defined as a ratio of a height of the walls 121 to a width of the walls 121 and may be between 1 to 1 and 10 to 1. For example, the aspect ratio (height to width) may be 6 to 1. The sub-pixel circuit 100 also already includes the bus-bar 127 and the S/D pad 129.

At operation 202, as illustrated in FIG. 3A, a plasma pre-treatment is performed on the sub-pixel circuit 100. The conditions of the plasma treatment may be different depending on the desired sub-pixel circuit 100. The plasma treatment may comprises two steps. The first step may involve a mixture of nitrogen (N₂) and oxygen (O₂) gases. The second may involve using a N₂ and hydrogen (H₂) mixture.

At operation 204, as illustrated in FIG. 3B, the ADL 108 is disposed over the substrate 102 and the plurality of metal layers 104. In some embodiments, the ADL 108 is disposed over the substrate 102 and the plurality of metal layers 104 using the common metal mask 302. In some embodiments, the ADL 108 is further patterned to expose the anodes 114 of the plurality of metal layer 104. In other embodiments, the ADL 108 exposes the anodes 114 of the plurality of metal layer 104. Each of the anodes 114 is associated with a discrete unit pixel 118 to be formed, such as the plurality of unit pixels 118, shown in FIG. 1A. The ADL 108 may be patterned by patterning a photoresist coating and subsequent etching. As described above, the ADL 108 may include one or more of a hole injection layer (HIL) and a hole transport layer (HTL). In some embodiments, the one or more of the HIL and the HTL may be included in the OLED material 120.

At operation 206, as illustrated in FIG. 3C, a first portion of OLED material 120 may be deposited over at least a portion of the ADL 108 at a first orientation. The first orientation may be formed by a first position of the substrate 102 and a first orientation of the evaporation deposition source 304 in relation to the walls 121. The at least a portion of the ADL 108 may be associated with at least a portion of a unit pixel 118 (e.g., a unit cell). The first portion of OLED material 120 may be deposited via an evaporation deposition process. In some embodiments, the evaporation deposition may include an oblique deposition process. When using an oblique deposition process, the thickness of the deposited OLED material 120 may be independent of the angle of deposition assuming scan speed is the same by material conservation (e.g., the oblique deposition does not increase material consumption). The oblique deposition process may involve using the location of the walls 121 and the orientation of the evaporation deposition source (e.g., evaporation nozzle) 304, as well as the position of the sub-pixel circuit 100. The walls 121 and the angle of deposition (which includes an emission angle 306 and an evaporation angle 308) set by the evaporation source 304 define the deposition angles (e.g., the walls 121 provide for a shadowing effect during evaporation deposition of the first portion of OLED material 120 with the angle of deposition set by the evaporation source 304). In order to deposit at a particular angle, the evaporation source 304 is configured to emit the first portion of OLED material 120 at a particular angle with regard to the walls 121. By adjusting the angle of deposition by manipulating the orientation of one or both of the evaporation source 304 and the position of the sub-pixel circuit 100, the evaporation source 304 can deposit the first portion of OLED material 120 at different angles to adjust where the first portion of OLED material 120 is disposed on the sub-pixel circuit 100.

In some embodiments, the evaporation deposition process used to deposit the first portion of OLED material 120 may include multiple sub-operations, and the evaporation deposition source 304 and/or the sub-pixel circuit 100 may be oriented differently during various sub-operations of operation 206 to deposit the first portion of OLED material 120 in each of the unit pixels 118 in a desired location. In addition, the placement of the sub-pixels 119A of each unit pixel 118 in a triangular array may also assist in the deposition of the first portion of OLED material 120 in the desired location. In some cases, the evaporation deposition process may create shadows on portions of the unit pixels 118 to be formed, and may deposit the first portion of OLED material 120 on the portions of the unit pixels 118 not covered by shadows. For example, the first portion of OLED material 120 may be deposited over the sub-pixel 119A to be formed of the unit pixel 118 and not over the sub-pixel 119B to be formed and the sub-pixel 119C to be formed, as illustrated in FIG. 3C. The first OLED material 120 may also be deposited in some portions of the unit pixel 118 as a result of the gaps 125 in the walls 121. In this example, the first portion of OLED material 120 disposed is configured to emit a red light when energized. The common metal mask 302 may be used during deposition of the first portion of the OLED material 120.

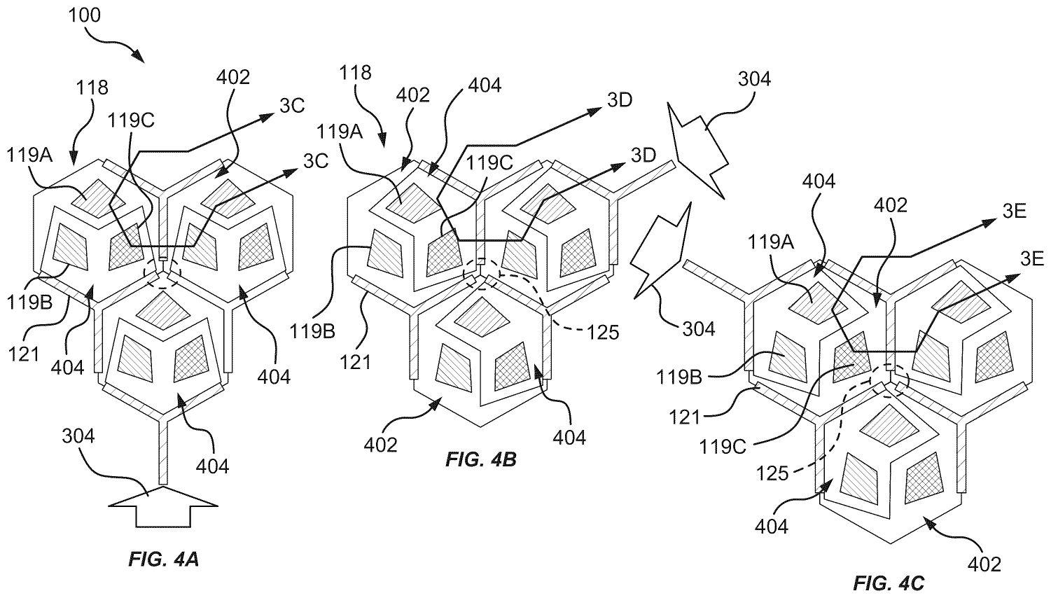

FIGS. 4A, 4B, and 4C are schematic, top-views of a sub-pixel circuit 100 during the evaporation deposition process of operations 206, 208, and 210 respectively, according to one or more of the embodiments described herein. The arrows marked 3C, 3D, and 3E of FIGS. 4A, 4B, and 4C, respectively, align to the arrows marked 4A, 4B, and 4C of FIGS. 3C, 3D, and 3E. In some embodiments, disposing the first portion of OLED material 120 over at least a portion of the ADL 108 results in a stable open area 402 (e.g., the area where the OLED material is deposited) and stable shadow area 404 (e.g., the area where the OLED material is not deposited as a result of the walls) formation, as illustrated in FIG. 4A. There may be an area between the open area 402 and the shadow area 404 (e.g., a process margin) where the deposited first portion of OLED material 120 forms a gradient (not shown). The deposition of the second portion of OLED material 120 and the third portion of OLED material 120 also result in stable open areas 402 (e.g., the area where the OLED material is deposited) and stable shadow areas 404 (e.g., the area where the OLED material is not deposited as a result of the walls) formation, as illustrated in FIGS. 4B and 4C, respectively. There may be an area between the open area 402 and the shadow area 404 (e.g., a process margin) where the deposited OLED material 120 forms a gradient (not shown). The orientation of the evaporation deposition source 304 and the position of the sub-pixel circuit 100 may be controlled throughout operations 206, 208, and 210 to achieve a preferred process margin.

At operation 208, as illustrated in FIG. 3D, a second portion of OLED material 120 may be disposed over at least a portion of the ADL 108 at a second orientation. The second orientation may be formed by a second position of the substrate 102 and a second orientation of the evaporation deposition source 304 in relation to the walls 121. In some embodiments, operation 208 is the same as or substantially similar to operation 206, which is described above. In some cases, the evaporation deposition process may create shadows on portions of the unit pixels 118 to be formed, and may deposit the second portion of OLED material 120 on the portions of the unit pixels 118 not covered by shadows. For example, the second portion of OLED material 120 may be deposited over the sub-pixel 119B to be formed of the unit pixel 118 and not over the sub-pixel 119A to be formed and the sub-pixel 119C to be formed, as illustrated in FIG. 3D. The second portion of OLED material 120 may also be deposited in some portions of the unit pixel 118 as a result of the gaps 125 in the walls 121. In some embodiments, there may be some overlap between the first portion of the OLED material 120 and the second portion of the OLED material 120 (not shown). Further, the second portion of OLED material 120 disposed is configured to emit a green light when energized. The common metal mask 302 may be used during deposition of the second portion of the OLED material 120.

At operation 210, as illustrated in FIG. 3E, a third portion of OLED material 120 may be disposed over at least a portion of the ADL 108 at a third orientation. The third orientation may be formed by a third position of the substrate 102 and a third orientation of the evaporation deposition source 304 in relation to the walls 121. In some embodiments, operation 210 is the same as or substantially similar to operation 206, which is described above. In some cases, the evaporation deposition process may create shadows on portions of the unit pixels 118 to be formed, and may deposit the third portion of OLED material 120 on the portions of the unit pixels 118 not covered by shadows. For example, the third portion of OLED material 120 may be deposited over the sub-pixel 119C to be formed of the unit pixel 118 and not over the sub-pixel 119A to be formed and the sub-pixel 119B to be formed, as illustrated in FIG. 3E. The third OLED material 120 may also be deposited in some portions of the unit pixel 118 as a result of the gaps 125 in the walls 121. In some embodiments, there may be some overlap between the first portion of the OLED material 120 and the second portion of the OLED material 120 (not shown). Further, the third portion of OLED material 120 disposed is configured to emit a blue light when energized. The common metal mask 302 may be used during deposition of the third portion of the OLED material 120.

At operation 212, as illustrated in FIG. 3F, one or more of an EIL and an ETL may be disposed over the OLED material 120 (shown as layer 109). In some embodiments, the one or more of the EIL and the ETL may be included in the OLED material 120. The common metal mask 302 may be used during deposition of the layer 109.

At operation 214, as illustrated in FIG. 3G, the cathode 124 may be disposed over the layer 109 (which includes one or both of the ETL and the EIL). As described above, the cathode 124 includes a conductive material, such as a metal. For example, the cathode 124 may include, but is not limited to, chromium, titanium, aluminum, ITO, or a combination thereof. A cathode open mask 312 may be used during deposition of the cathode 124.

At operation 216, as illustrated in FIG. 3H, the first encapsulation layer 126 (e.g., thin film encapsulation (TFE) layer) may be disposed over the cathode 124. As described above, the first encapsulation layer 126 may be or may correspond to a local passivation layer. The first encapsulation layer 126 of a respective unit pixel 118 is disposed over the cathode 124 (and the OLED material 120) and the PDL structures 106. The first encapsulation layer 126 includes a non-conductive inorganic material, such as the silicon-containing material. The silicon-containing material may include Si₃N₄ containing materials. An encapsulation layer mask 314 may be used during deposition of the first encapsulation layer 126.

At operation 218, as illustrated in FIG. 3I, the plug 122 may be disposed over the first encapsulation layer 126. As described above, the plug 122 may include, a photoresist, a color filter, or a photosensitive monomer. The plug 122 have a plug transmittance that is matched or substantially matched to an OLED transmittance of the OLED material 120. The plug 122 may each be the same material and match the OLED transmittance. The plug 122 may be different materials that match the OLED transmittance of each respective sub-pixel of the plurality of sub-pixels 119A, 119B, 119C. The matched or substantially matched resist transmittance and OLED transmittance allow for the plug 122 to remain over the sub-pixels 119A, 119B, 119C without blocking the emitted light from the OLED material 120. The plug 122 is able to remain in place and thus do not require a lift off procedure to be removed from the sub-pixel circuit 100. In some embodiments, the plug 122 may be an inkjet layer. The inkjet layer may include an acrylic material.

At operation 220, as illustrated in FIG. 3J, the second encapsulation layer 130 (e.g., thin film encapsulation (TFE) layer) may be disposed over the plug 122. As described above, the second encapsulation layer 130 may be or may correspond to a local passivation layer. The second encapsulation layer 130 of a respective unit pixel 118 is disposed over the cathode 124 (and the OLED material 120) and the PDL structures 106. The second encapsulation layer 130 includes a non-conductive inorganic material, such as the silicon-containing material. The silicon-containing material may include Si₃N₄ containing materials. The encapsulation layer mask 314 may be used during deposition of the second encapsulation layer 130.

In summation, forming the sub-pixel circuit 100 using the shadowing effect due to the location of the walls 121, the orientation of the evaporation deposition source 304 used to deposit the OLED material 120, and the position of the substrate 102 may create a more stable open area (e.g., the area where the OLED material 120 is deposited) and shadow area (e.g., the area where the OLED material 120 is not deposited as a result of the walls 121) formation. In addition, the gaps 125 between adjacent walls 121 of the sub-pixel circuit may enable a continuous current path through the sub-pixels 119A, 119B, and 119C along the cathode 124 of the sub-pixel circuit 100. The sub-pixel circuit 100 may also be formed without the use of conventional fine metal mask (FMM) and lithography technology, and may have an increased pixel density (PPI).

While the foregoing is directed to embodiments of the present disclosure, other and further embodiments of the disclosure may be devised without departing from the basic scope thereof, and the scope thereof is determined by the claims that follow.

What is claimed is:

1. A sub circuit, comprising:
a backplane layer disposed over a substrate; and
a plurality of walls disposed over the backplane layer, wherein the plurality of walls define a plurality of gaps, wherein the plurality of walls and the plurality of gaps define one or more unit pixels, and wherein the one or more unit pixels each comprise a sub-pixel, each sub-pixel comprising:
an anode;
an organic light-emitting diode (OLED) material disposed over the anode; and
a cathode disposed over the OLED material and the plurality of walls.

2. The sub circuit of claim 1, wherein the plurality of walls comprise at least one Y-shaped wall.

3. The sub circuit of claim 1, wherein the plurality of gaps are configured to enable a continuous current path through each sub-pixel of the one or more unit pixels.

4. The sub circuit of claim 3, wherein each sub-pixel of the one or more unit pixels comprises an encapsulation layer disposed over the cathode.

5. The sub circuit of claim 1, wherein each of the one or more unit pixels comprises three sub-pixels, the three sub-pixels arranged in a triangular array.

6. The sub circuit of claim 5, wherein each of the three sub-pixels are configured to emit a different color when energized.

7. A method, comprising:
positioning a substrate, the substrate comprising one or more unit pixels, wherein each of the one or more unit pixels comprises a sub-pixel opening, wherein each sub-pixel opening comprises an anode, wherein each of the one or more unit pixels is partially surrounded by a plurality of walls, wherein the plurality of walls define a plurality of gaps, and wherein the plurality of walls and the plurality of gaps define the one or more unit pixels;
depositing a first portion of OLED material on a first portion of the one or more unit pixels at a first orientation, the first orientation formed by a first position of the substrate and a first orientation of an evaporation deposition source;
depositing a second portion of OLED material on a second portion of the one or more unit pixels at a second orientation, the second orientation formed by a second position of the substrate and a second orientation of the evaporation deposition source;
depositing a third portion of OLED material on a third portion of the one or more unit pixels at a third orientation, the third orientation formed by a third position of the substrate and a third orientation of the evaporation deposition source; and
disposing a cathode over the first portion of OLED material, the second portion of OLED material, and the third portion of OLED material.

8. The method of claim 7, wherein the first portion of OLED material, the second portion of OLED material, and the third portion of OLED material are deposited using an oblique deposition process.

9. The method of claim 7, wherein a ratio between a height of the plurality of walls and a width of the plurality of walls is between 1 to 1 and 10 to 1.

10. The method of claim 7, wherein the plurality of walls comprise at least one Y-shaped wall.

11. The method of claim 10, wherein the first orientation is formed by the first position of the substrate and the first orientation of an evaporation deposition source in relation to the at least one Y-shaped wall.

12. A sub circuit, comprising:
a substrate;
a pixel defining layer (PDL) disposed over the substrate, the PDL exposing anodes disposed over the substrate; and
a Y-shaped wall disposed over the PDL, wherein the Y-shaped wall partially surrounds a unit pixel, wherein the unit pixel comprises three sub-pixels.

13. The sub circuit of claim 12, wherein a first portion of organic light-emitting diode (OLED) material is disposed over a first portion of the unit pixel, and wherein the first portion of the OLED material results from a first position of the substrate and a first orientation of an evaporation deposition source in relation to the Y-shaped wall during deposition.

14. The sub circuit of claim 12, wherein the three sub-pixels are arranged in a triangular array.

15. The sub circuit of claim 12, wherein the Y-shaped wall is configured to enable a continuous current path through each sub-pixel of the unit pixel.

16. The sub circuit of claim 12, wherein each of the three sub-pixels are configured to emit a different color when energized.

17. A method, comprising:
positioning a substrate, the substrate comprising a unit pixel, wherein the unit pixel comprises three sub-pixel openings, wherein each sub-pixel opening comprises an anode defined by a plurality of pixel-defining layer (PDL) structures, and wherein the unit pixel is partially surrounded by a Y-shaped wall; and
depositing OLED material over three portions of the unit pixel, wherein the OLED material is deposited at three orientations, each orientation corresponding to deposition in a sub-pixel opening of the three sub-pixel openings.

18. The method of claim 17, wherein one of the three orientations is formed by a first position of the substrate and a first orientation of an evaporation deposition source in relation to the Y-shaped wall.

19. The method of claim 17, wherein the OLED material is deposited using an oblique deposition process.

20. The method of claim 17, wherein a ratio between a height of the Y-shaped wall and a width of the Y-shaped wall is between 1 to 1 and 10 to 1.
